(19) United States
(12) Patent Application Publication
(10) Pub. No.: US 2024/0014065 A1
(43) Pub. Date: Jan. 11, 2024

(54) FLAT SUSCEPTOR WITH GRID PATTERN AND VENTING GROOVES ON SURFACE THEREOF

(71) Applicant: Applied Materials, Inc., Santa Clara, CA (US)

(72) Inventors: Zhepeng CONG, San Jose, CA (US); Balakrishnam R. JAMPANA, Santa Clara, CA (US); Masato ISHII, Sunnyvale, CA (US); Shawn Joseph BONHAM, Mesa, AZ (US); James M. AMOS, Apache Junction, AZ (US); Kirk Allen FISHER, Tempe, AZ (US); Philip Michael AMOS, Apache Junction, AZ (US); Cathryne A. RYAN, Minden, NV (US); Aimee S. ERHARDT, Tempe, AZ (US); Xinning LUAN, Tempe, AZ (US); Hui CHEN, Tempe, AZ (US)

(21) Appl. No.: 17/860,891

(22) Filed: Jul. 8, 2022

(51) Int. Cl. H01L 21/687

(52) U.S. Cl. CPC H01L 21/68757; H01L 21/68785

(57) ABSTRACT

A susceptor for use in a processing chamber for supporting a wafer includes a susceptor substrate having a susceptor ledge on an outer circumferential edge of a front side of the susceptor substrate, wherein a pocket within the susceptor ledge is configured to hold a wafer to be processed in a processing chamber, and a coating layer deposited on the susceptor substrate, wherein a surface of the susceptor ledge is textured with a plurality of venting groove lines, a surface of the pocket is textured with a first pattern, and a surface of a back side of the susceptor substrate opposite the front side is textured with a second pattern.

### BACKGROUND

### Field

Examples described herein generally relate a susceptor to be used in semiconductor wafer processing, and more particularly to a susceptor having a grid pattern and venting grooves on a surface thereof to be used in an epitaxy deposition process.

### Description of the Related Art

A chemical vapor deposition (CVD) process is used in semiconductor wafer processing, along with other processes, for epitaxially depositing a thin layer (generally, less than 10 micron) on a wafer. The CVD process requires a wafer held in a pocket in a susceptor be heated up to an elevated temperature, for example, about 1200° C. The wafer is typically heated from room temperature to the elevated temperature within approximately 30 minutes. During such wafer processing, in a susceptor having a flat pocket, air is trapped between a wafer and a surface of the flat pocket and the wafer slides within the pocket. This wafer sliding damages the pocket of the susceptor, and affects quality of epitaxy deposition on the wafer.

Therefore, there is need for a susceptor that is able to alleviate water sliding thereon.

### SUMMARY

Embodiments of the disclosure include a susceptor for use in a processing chamber for supporting a wafer. The susceptor includes a susceptor substrate having a susceptor ledge on an outer circumferential edge of a front side of the susceptor substrate, wherein a pocket within the susceptor ledge is configured to hold a wafer to be processed in a processing chamber, and a coating layer deposited on the susceptor substrate, wherein a surface of the susceptor ledge is textured with a plurality of venting groove lines, a surface of the pocket is textured with a first pattern, and a surface of a back side of the susceptor substrate opposite the front side is textured with a second pattern.

Embodiments of the disclosure also include a processing chamber. The processing chamber includes a chamber body in fluid communication with one or more gas sources, and a substrate support assembly comprising a susceptor, wherein the susceptor includes a susceptor substrate having a susceptor ledge on an outer circumferential edge of a front side of the susceptor substrate, wherein a pocket within the susceptor ledge is configured to hold a wafer to be processed in the processing chamber, and a coating layer deposited on the susceptor substrate, wherein a surface of the susceptor ledge is textured with a plurality of venting groove lines, a surface of the pocket is textured with a first pattern, and a surface of a back side of the susceptor substrate opposite the front side is textured with a second pattern.

Embodiments of the disclosure further include a processing system. The processing system includes a processing chamber including a chamber body in fluid communication with one or more gas sources, a substrate support assembly comprising a susceptor, wherein the susceptor includes a susceptor substrate having a susceptor ledge on an outer circumferential edge of a front side of the susceptor substrate, wherein a pocket within the susceptor ledge is configured to hold a wafer to be processed in the processing chamber, and a coating layer deposited on the susceptor substrate, wherein a surface of the susceptor ledge is textured with a plurality of venting groove lines, a surface of the pocket is textured with a first pattern, and a surface of a back side of the susceptor substrate opposite the front side is textured with a second pattern, and a controller configured to cause the processing system to perform an epitaxy deposition process in the processing chamber.

### BRIEF DESCRIPTION OF THE DRAWINGS

So that the manner in which the above recited features of the present disclosure can be understood in detail, a more particular description, briefly summarized above, may be had by reference to examples, some of which are illustrated in the appended drawings. It is to be noted, however, that the appended drawings illustrate only some examples and are therefore not to be considered limiting of the scope of this disclosure, for the disclosure may admit to other equally effective examples.

FIG. 1 is a schematic top-view diagram of an example multi-chamber processing system according to some examples of the present disclosure.

FIG. 2 is a cross-sectional view of a thermal processing chamber that may be used to perform epitaxial growth according to some examples of the present disclosure.

FIGS. 3A and 3B are a cross-sectional view scanning electron Microscope (SEM) image and a top view SEM image of a susceptor according to one embodiment.

FIGS. 4A, 4B, 4C, 4D, 4E, and 4F are a cross-sectional view, a front view, an enlarged front view, an enlarged cross-sectional view, an enlarged front view, and an enlarged cross-sectional view of a portion of a susceptor according to one embodiment.

To facilitate understanding, identical reference numerals have been used, wherever possible, to designate identical elements that are common to the figures.

### DETAILED DESCRIPTION

Generally, examples described herein relate to a susceptor to hold a wafer thereon for semiconductor wafer processing, and more particularly to a susceptor having a grid pattern on a pocket and venting grooves on a ledge on a front side, and a mirrored grid pattern on a back side, to be used in an epitaxy deposition process. Due to the venting grooves that are in fluid communication with the grid pattern on the front side, wafer sliding in the pocket is reduced, reducing damage to the susceptor and improving quality of epitaxy deposition on the wafer. Due to the mirrored grid pattern on the back side of the susceptor, interfacial stress between a susceptor substrate and a coating layer is reduced during an epitaxy deposition process, reducing warping and bowing of the susceptor and increasing the flatness of the susceptor.

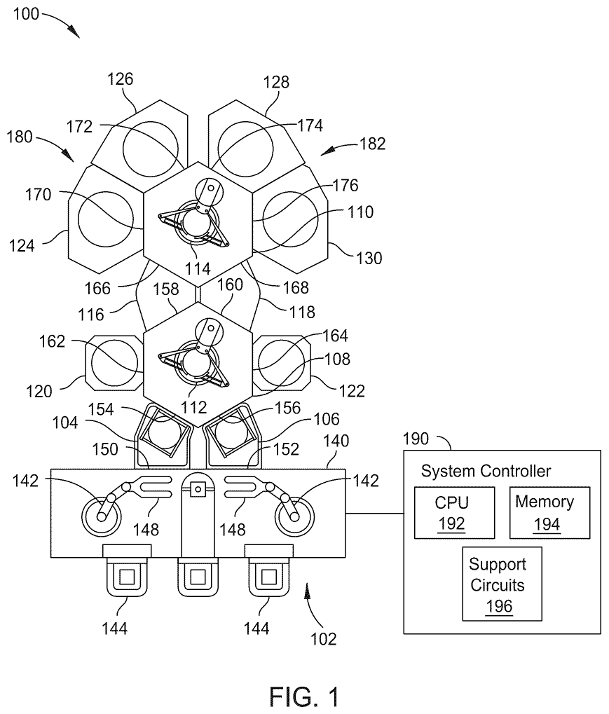

FIG. 1 is a schematic top-view diagram of an example of a multi-chamber processing system 100 according to some examples of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide for an integrated solution for some processing of wafers.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough; otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some examples, the processing chamber 122 can be capable of performing a cleaning process; the processing chamber 120 can be capable of performing an etch process; and the processing chambers 124, 126, 128, 130 can be capable of performing respective epitaxial growth processes. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

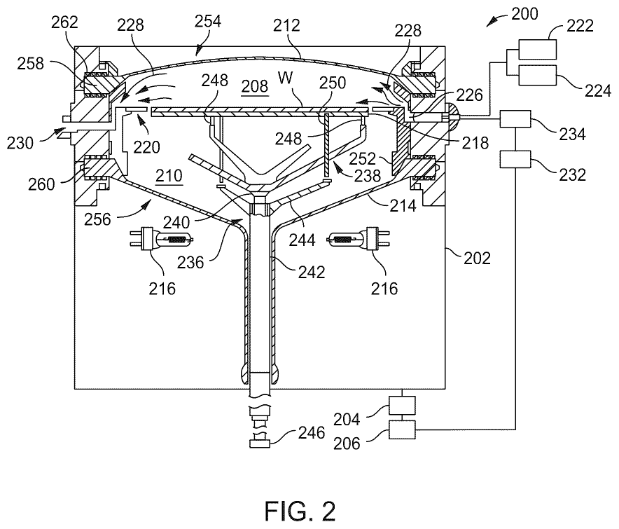

FIG. 2 is a cross-sectional view of a processing chamber 200 that may be used to perform epitaxial growth. The processing chamber 200 may be any one of processing chambers 120, 122, 124, 126, 128, 130 from FIG. 1. Non-limiting examples of the suitable processing chambers that may be modified according to embodiments disclosed herein may include the RP EPI reactor, Elvis chamber, and Lennon chamber, which are all commercially available from Applied Materials, Inc. of Santa Clara, Calif. The processing chamber 200 may be added to a CENTURA® integrated processing system available from Applied Materials, Inc., of Santa Clara, Calif. While the processing chamber 200 is described below to be utilized to practice various embodiments described herein, other semiconductor processing chambers from different manufacturers may also be used to practice the embodiment described in this disclosure.

The processing chamber 200 includes a chamber body 202, a support system 204, and a controller 206. The chamber body 202 includes an upper portion 208 and a lower portion 210. The upper portion 208 includes the area within the chamber body 202 between an upper dome 212 and a wafer W. The lower portion 210 includes the area within the chamber body 202 between a lower dome 214 and the bottom of the wafer W. Deposition processes generally occur on the upper surface of the wafer W within the upper portion 208.

The support system 204 includes components used to execute and monitor pre-determined processes, such as the growth of epitaxial films in the processing chamber 200. A controller 206 is coupled to the support system 204 and is adapted to control the processing chamber 200 and support system 204. The controller 206 may be the system controller 190 or a controller controlled by the system controller 190 for controlling processes within the processing chamber 200.

The processing chamber 200 includes a plurality of heat sources, such as lamps 216, which are adapted to provide thermal energy to components positioned within the processing chamber 200. For example, the lamps 216 may be adapted to provide thermal energy to the wafer W, a susceptor 218, and/or a preheat ring 220. The lower dome 214 may be formed from an optically transparent material, such as quartz, to facilitate the passage of thermal radiation therethrough. It is contemplated that lamps 216 may be positioned to provide thermal energy through the upper dome 212 as well as the lower dome 214.

The chamber body 202 includes a plurality of plenums formed therein. The plenums are in fluid communication with one or more gas sources 222, such as a carrier gas, and one or more precursor sources 224, such as deposition gases and dopant gases. For example, a first plenum 226 may be adapted to provide a deposition gas 228 therethrough into the upper portion 208 of the chamber body 202, while a second plenum 230 may be adapted to exhaust the deposition gas 228 from the upper portion 208. In such a manner, the deposition gas 228 may flow parallel to an upper surface of the wafer W.

In cases where a liquid precursor is used, the processing chamber 200 may include a liquid vaporizer 232 in fluid communication with a liquid precursor source 234. The liquid vaporizer 232 is be used for vaporizing liquid precursors to be delivered to the processing chamber 200. While not shown, it is contemplated that the liquid precursor source 234 may include, for example, one or more ampules of precursor liquid and solvent liquid, a shut-off valve, and a liquid flow meter (LFM).

A substrate support assembly 236 is positioned in the lower portion 210 of the chamber body 202. The substrate support assembly 236 is illustrated supporting a wafer W in a processing position. The substrate support assembly 236 includes a susceptor support shaft 238 formed from an optically transparent material and the susceptor 218 supported by the susceptor support shaft 238. A shaft 240 of the susceptor support shaft 238 is positioned within a shroud 242 to which lift pin contacts 244 are coupled. The susceptor support shaft 238 is rotatable in order to facilitate the rotation of the wafer W during processing. Rotation of the susceptor support shaft 238 is facilitated by an actuator 246 coupled to the susceptor support shaft 238. The shroud 242 is generally fixed in position, and therefore, does not rotate during processing. Support pins 248 couple the susceptor support shaft 238 to the susceptor 218.

Lift pins 250 are disposed through openings (not labeled) formed in the susceptor support shaft 238. The lift pins 250 are vertically actuatable and are adapted to contact the underside of the substrate W to lift the substrate W from a processing position (as shown) to a substrate removal position.

The preheat ring 220 is removably disposed on a lower liner 252 that is coupled to the chamber body 202. The preheat ring 220 is disposed around the internal volume of the chamber body 202 and circumscribes the substrate W while the substrate W is in a processing position. The preheat ring 220 facilitates preheating of a process gas as the process gas enters the chamber body 202 through the first plenum 226 adjacent to the preheat ring 220.

A central window portion 254 of the upper dome 212 and a bottom portion 256 of the lower dome 214 may be formed from an optically transparent material such as quartz. A peripheral flange 258 of the upper dome 212, which engages the central window portion 254 around a circumference of the central window portion 254, a peripheral flange 260 of the lower dome 214, which engages the bottom portion 256 around a circumference of the bottom portion 256, may all be formed from an opaque quartz to protect O-rings 262 in proximity to the peripheral flanges from being directly exposed to the heat radiation. The peripheral flange 258 may be formed of an optically transparent material such as quartz.

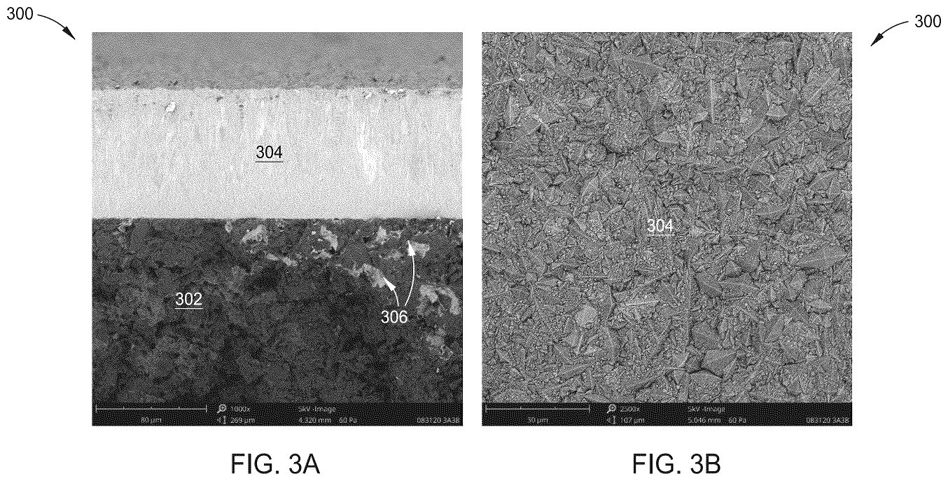

FIGS. 3A and 3B are a cross-sectional view scanning electron Microscope (SEM) image and a top view SEM image of a susceptor 300 according to one embodiment. The susceptor 300 may be the susceptor 218 disposed in the processing chamber 200 from FIG. 2. The susceptor 300 includes a susceptor substrate 302 and a coating layer 304. The susceptor substrate 302 is formed of graphite. The coating layer 304 is formed of silicon carbide (SiC). The graphite susceptor substrate 302 may be porous having pores 306, into which silicon carbide (SiC) tendrils are formed. This formation of silicon carbide (SiC) provides improved mechanical properties in the susceptor 300.

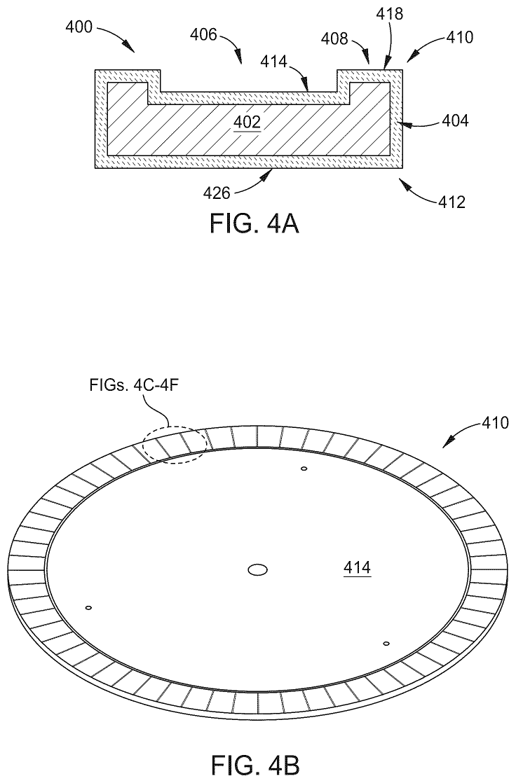

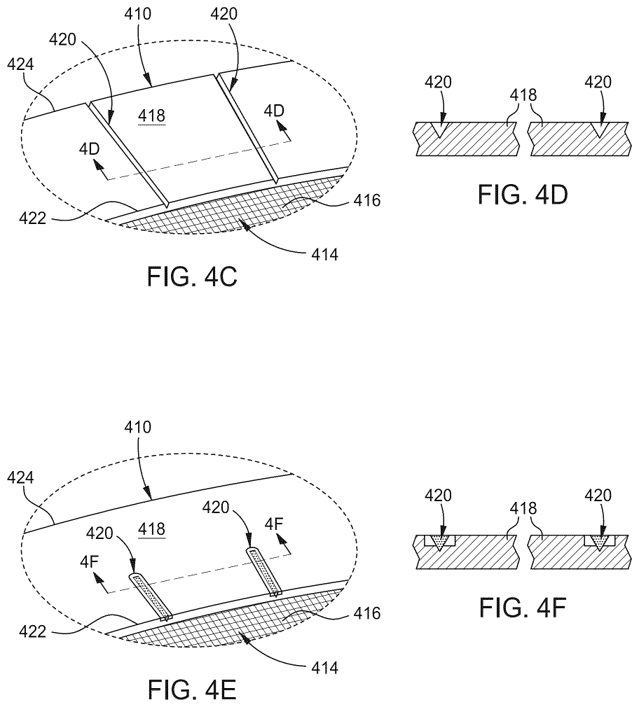

FIG. 4A is a schematic cross-sectional view of a portion of a susceptor 400 according to the embodiments described herein. FIGS. 4B, 4C, 4D, 4E, and 4F are a front view, an enlarged front view, an enlarged cross-sectional view, an enlarged front view, and an enlarged cross-sectional view of the susceptor 400. The susceptor 400 may be the susceptor 218 disposed in the processing chamber 200 from FIG. 2.

The susceptor 400 includes a susceptor substrate 402 coated with a coating layer 404. The susceptor substrate 402 may be formed of graphite having at least 99% purity and prepared by saw-cutting any suitable graphite billet into a disc-shaped plate and grinding surfaces of the disc-shaped plate. The susceptor substrate 402 may have a diameter of between about 150 mm and about 400 mm, for example, about 370 mm, and a thickness of between about 1 mm and about 15 mm, for example, about 3.70 mm. The coating layer 404 may be formed of silicon carbide (SiC) and formed on the susceptor substrate 402 by conformally depositing silicon carbide (SiC) on the susceptor substrate 402 by a CVD process using an organosilicon precursor. The coating layer 404 may have a thickness of between about 40 μm and about 300 μm, for example, about 80 μm.

The susceptor 400 includes a pocket 406 to hold a wafer (not shown) within a susceptor ledge 408 on the outer circumferential edge of a front side 410 of the susceptor 400. The pocket 406 may be formed by a surface treatment, such as precise machining for applying a specific surface structure to a surface of the susceptor substrate 402 using conventional methods known in the art. The pocket 406 may be a cylindrical recess having a depth of between about 0.30 mm and about 1.00 mm, for example, about 0.40 mm. The pocket 406 may have a diameter that is larger than a diameter of a wafer by about between about 2 mm and 5 mm, for example, between about 302 mm and about 305 mm, to hold a 300 mm wafer. This margin around a wafer may avoid damage to the wafer when the wafer is loaded within the pocket 406. The pocket 406 may be designed to hold a wafer having a diameter of 2, 4, 6, 8, or 12 inches. The susceptor ledge 408 may have a width of between about 15 mm and about 70 mm, for example, about 35 mm.

A surface 414 of the pocket 406 on the front side 410 is textured with a grid pattern 416 of intersecting grid groove lines, as shown in FIGS. 4C and 4E, by precise machining. Each of the grid groove lines of the grid pattern 416 may have a depth of between about 0.10 mm and about 1.30 mm, for example, between about 0.15 mm and 0.45 mm, from the surface 414 of the pocket 406, a width of between about 0.20 mm and about 3.00 mm, for example, about 0.43 mm, and a pitch of between about 0.80 mm and about 3.00 mm, for example, about 1.14 mm.

A surface 418 of the susceptor ledge 408 on the front side 410 is textured with venting groove lines 420 radially extending from an inner circumferential edge 422 towards an outer circumferential edge 424 of the susceptor ledge 408 with equal angles between adjacent venting groove lines 420. Each venting groove line 420 is aligned with and in fluid communication with one grid groove line of the grid pattern 416 at the inner circumferential edge 422 of the susceptor ledge 408. Each venting groove line 420 has the same or similar cross section as that of the grid groove line of the grid pattern 416, for example, having a depth of about 0.30 mm and about 1.30 mm, for example, about 0.65 mm and 0.75 mm, and a width of between about 0.20 mm and about 3.00 mm, for example, about 0.43 mm. The number of venting groove lines 420 may be between 3 and 360 (i.e., an angle between adjacent venting groove lines 420 may be between 1° and 120°). When a wafer is held on the susceptor 400 having the venting groove lines 420 thereon during an epitaxy deposition process, air between the wafer and the pocket 406 is vented through the venting groove lines 420 and the grid groove lines of the grid pattern 416, and thus the wafer can be centered in the pocket 406. Therefore, an epitaxy uniformity on the wafer may be improved and a damage to the susceptor 400 may be reduced by sliding of the wafer on the susceptor 400.

In some embodiments, the venting groove lines 420 extend for the entire radial distance between the inner circumferential edge 422 and the outer circumferential edge 424, as shown in FIG. 4C. In some other embodiments, the venting groove lines 420 extend from the inner circumferential edge 422 for a partial radial distance towards the outer circumferential edge 424, as shown in FIG. 4E. A cross-sectional shape of each venting groove line 420 may be a V-shape, as shown in FIG. 4C, or a combination of a rectangular shape near the surface 418 and a V-shape below the rectangular shape, as shown in FIG. 4F. Each venting groove line 420 may have a U-shaped cross-section, a square shaped cross-section, or a cylinder shaped cross-section (not shown).

A surface 426 of the back side 412 is machined to a flat and planer surface and textured with patterns. One example of the patterns is a grid pattern that matches with the grid pattern 416 applied to the surface 414 of the pocket 406 on the front side 410. The grid pattern 416 may have intersecting grid groove lines each having a depth of between about 0.10 mm and about 2.60 mm, for example, about 0.85 mm and about 1.15 mm, from the surface 426 of the back side 412, a width of between about 0.20 mm and about 3.00 mm, for example, about 0.43 mm, and a pitch of between about 0.80 mm and about 3.00 mm, for example, about 1.14 mm. The same grid pattern 416 applied to the surface 426 of the back side 412 as the surface 414 of the pocket 406 may reduce warpage and bowing of the susceptor.

The embodiments described herein provide a susceptor to hold a wafer thereon in an epitaxy deposition process, having a textured pocket and a ledge with venting grooves on a front side, and a textured back side. The venting grooves that are in fluid communication with the grid groove lines reduce air trapping under a wafer and assist centering the wafer to the center of the susceptor. As a result, wafer sliding in the pocket of the susceptor, and thus damage to the susceptor may be reduced. The mirrored grid pattern applied to the back side of the susceptor, interfacial stress between a susceptor substrate and a coating layer is reduced during an epitaxy deposition process, reducing warping and bowing of the susceptor and increasing the flatness of the susceptor.

While the foregoing is directed to specific embodiments, other and further embodiments may be devised without departing from the basic scope thereof, and the scope thereof is determined by the claims that follow.

1. A susceptor for use in a processing chamber for supporting a wafer, the susceptor comprising:
a susceptor substrate having a susceptor ledge on an outer circumferential edge of a front side of the susceptor substrate, wherein a pocket within the susceptor ledge is configured to hold a wafer to be processed in a processing chamber; and
a coating layer deposited on the susceptor substrate, wherein
a surface of the susceptor ledge is textured with a plurality of venting groove lines,
a surface of the pocket is textured with a first pattern, and
a surface of a back side of the susceptor substrate opposite the front side is textured with a second pattern.

2. The susceptor of claim 1, wherein the first pattern is a first grid pattern of intersecting grid groove lines.

3. The susceptor of claim 2, wherein each grid groove line of the first grid pattern has a depth of between 0.10 mm and 1.30 mm from the surface of the pocket, a width of between 0.20 mm and 3.00 mm, and a pitch of between 0.80 mm and 3.00 mm.

4. The susceptor of claim 2, wherein each venting groove line of the plurality of venting groove lines radially extends from an inner circumferential edge towards an outer circumferential edge of the susceptor ledge and is in fluid communication with one grid groove line of the first grid pattern at the inner circumferential edge of the susceptor ledge.

5. The susceptor of claim 4, wherein each venting groove line of the plurality of venting groove lines has a depth of 0.30 mm and 1.30 mm, and a width of between 0.20 mm and 3.00 mm.

6. The susceptor of claim 2, wherein the second pattern is a second grid pattern of intersecting grid groove lines.

7. The susceptor of claim 6, wherein each grid groove line of the second grid pattern has a depth of between 0.10 mm and 2.60 mm from the surface of the back side, a width of between 0.20 mm and 3.00 mm, and a pitch of between 0.80 mm and 3.00 mm.

8. The susceptor of claim 1, wherein the susceptor substrate is a disc-shaped plate having a thickness of between 1 mm and 15 mm.

9. The susceptor of claim 1, wherein the pocket is a cylindrical recess having a diameter of between 302 mm and 305 mm, and a depth of between 0.30 mm and 1.00 mm.

10. The susceptor of claim 1, wherein
the susceptor substrate comprises graphite, and
the coating layer comprises silicon-carbide (SiC).

11. A processing chamber, comprising:
a chamber body in fluid communication with one or more gas sources; and
a substrate support assembly comprising a susceptor, wherein the susceptor comprises:
a susceptor substrate having a susceptor ledge on an outer circumferential edge of a front side of the susceptor substrate, wherein a pocket within the susceptor ledge is configured to hold a wafer to be processed in the processing chamber; and
a coating layer deposited on the susceptor substrate, wherein
a surface of the susceptor ledge is textured with a plurality of venting groove lines,
a surface of the pocket is textured with a first pattern, and
a surface of a back side of the susceptor substrate opposite the front side is textured with a second pattern.

12. The processing chamber of claim 11, wherein
the first pattern is a first grid pattern of intersecting grid groove lines, and
each grid groove line of the first grid pattern has a depth of between 0.10 mm and 1.30 mm from the surface of the pocket, a width of between 0.20 mm and 3.00 mm, and a pitch of between 0.80 mm and 3.00 mm.

13. The processing chamber of claim 12, wherein
each venting groove line of the plurality of venting groove lines radially extends from an inner circumferential edge towards an outer circumferential edge of the susceptor ledge and is in fluid communication with one grid groove line of the first grid pattern at the inner circumferential edge of the susceptor ledge, and
each venting groove line of the plurality of venting groove lines has a depth of 0.30 mm and 1.30 mm, and a width of between 0.20 mm and 3.00 mm.

14. The processing chamber of claim 12, wherein
the second pattern is a second grid pattern of intersecting grid groove lines, and
each grid groove line of the second grid pattern has a depth of between 0.10 mm and 2.60 mm from the surface of the back side, a width of between 0.20 mm and 3.00 mm, and a pitch of between 0.80 mm and 3.00 mm.

15. The processing chamber of claim 11, wherein
the susceptor substrate is a disc-shaped plate having a thickness of between 1 mm and 15 mm, and
the pocket is a cylindrical recess having a diameter of between 302 mm and 305 mm, and a depth of between 0.30 mm and 1.00 mm.

16. The processing chamber of claim 11, wherein
the susceptor substrate comprises graphite, and
the coating layer comprises silicon-carbide (SiC).

17. A processing system, comprising:
a processing chamber comprising:
a chamber body in fluid communication with one or more gas sources;
a substrate support assembly comprising a susceptor, wherein the susceptor comprises:
a susceptor substrate having a susceptor ledge on an outer circumferential edge of a front side of the susceptor substrate, wherein a pocket within the susceptor ledge is configured to hold a wafer to be processed in the processing chamber; and
a coating layer deposited on the susceptor substrate, wherein
a surface of the susceptor ledge is textured with a plurality of venting groove lines,
a surface of the pocket is textured with a first pattern, and
a surface of a back side of the susceptor substrate opposite
the front side is textured with a second pattern; and
a controller configured to cause the processing system to perform an epitaxy deposition process in the processing chamber.

18. The processing system of claim 17, wherein
the first pattern is a first grid pattern of intersecting grid groove lines,
each grid groove line of the first grid pattern has a depth of between 0.10 mm and 1.30 mm from the surface of the pocket, a width of between 0.20 mm and 3.00 mm, and
a pitch of between 0.80 mm and 3.00 mm,
each venting groove line of the plurality of venting groove lines radially extends from an inner circumferential edge towards an outer circumferential edge of the susceptor ledge and is in fluid communication with one grid groove line of the first grid pattern at the inner circumferential edge of the susceptor ledge,
each venting groove line of the plurality of venting groove lines has a depth of 0.30 mm and 1.30 mm, and a width of between 0.20 mm and 3.00 mm,
the second pattern is a second grid pattern of intersecting grid groove lines, and
each grid groove line of the second grid pattern has a depth of between 0.10 mm and 2.60 mm from the surface of the back side, a width of between 0.20 mm and 3.00 mm, and a pitch of between 0.80 mm and 3.00 mm.

19. The processing system of claim 17, wherein
the susceptor substrate is a disc-shaped plate having a thickness of between 1 mm and 15 mm, and
the pocket is a cylindrical recess having a diameter of between 302 mm and 305 mm, and a depth of between 0.30 mm and 1.00 mm.

20. The processing system of claim 17, wherein
the susceptor substrate comprises graphite, and
the coating layer comprises silicon-carbide (SiC).
